(19) United States
(12) Patent Application Publication
(10) Pub. No.: US 2026/0063503 A1
(43) Pub. Date: Mar. 5, 2026

(54) METHODS AND SYSTEMS FOR MONITORING AND EARLY WARNING OF SAFETY STATUSES OF BRIDGES

(71) Applicant: HENGXIANG TECHNOLOGY INC., LTD., Hengshui (CN)

(72) Inventors: Baoquan LIU, Hengshui (CN); Guangye WANG, Hengshui (CN); Zhongyuan TIAN, Hengshui (CN); Pan GU, Hengshui (CN); Kunkun WANG, Hengshui (CN); Ruizhao LU, Hengshui (CN); Zezheng ZHANG, Hengshui (CN); Xu GUO, Hengshui (CN); Mengmeng SONG, Hengshui (CN)

(73) Assignee: HENGXIANG TECHNOLOGY INC., LTD., Hengshui (CN)

(21) Appl. No.: 19/275,937

(22) Filed: Jul. 21, 2025

(30) Foreign Application Priority Data
Aug. 27, 2024 (CN) 202411181423.8

(51) Int. Cl. G01M 5/00; G06F 30/13; H04Q 9/02

(52) U.S. Cl. CPC G01M 5/0008; G01M 5/0041; G06F 30/13; H04Q 9/02

(57) ABSTRACT

A method and a system for monitoring and early warning of a safety status of a bridge are provided. The method includes: in response a bridge to be monitored being a new bridge, collecting first monitoring data of the bridge in real time, determining a first monitoring data threshold set, performing a first comparison between the first monitoring data and the first monitoring data threshold set to obtain a first comparison result, and displaying the first comparison result in real time; in response to the bridge to be monitored being an old bridge, collecting second monitoring data of the bridge in real time, determining a second monitoring data threshold set, performing a second comparison between the second monitoring data and the second threshold to obtain a second comparison result, and displaying the second comparison result in real time.

### CROSS-REFERENCE TO RELATED APPLICATIONS

This application claims priority to Chinese application No. 202411181423.8, filed Aug. 27, 2024, the entire contents of which are incorporated herein by reference.

### TECHNICAL FIELD

The present disclosure relates to the field of bridge monitoring, and in particular, to a method and a system for monitoring and early warning of a safety status of a bridge.

### BACKGROUND

Bridges refer to a structures built over river, lake, or sea to allow vehicles and pedestrians to pass smoothly. To meet the demands of the rapidly developing modern transportation industry, the bridges have been extended to structures spanning mountain streams, poor geological conditions, or other transportation needs to facilitate more convenient passage.

However, factors such as earthquakes, floods, extreme wind forces, geological changes, and overloading may cause damage to bridge structures. Once the bridge is damaged, vehicle and pedestrian traffic may be easily hindered subsequently, thereby affecting continued use of the bridge. Moreover, existing methods for bridge safety monitoring are typically based on preset fixed monitoring parameters and fixed thresholds. With the advancement of economy and technology, modern bridge infrastructure consists of a new bridge and an old bridge in simultaneous use. Due to objective factors such as differences in service life and design standards between the new bridge and the old bridge, applying the same parameter for testing and early warning makes it difficult to accurately assess an overall condition of the bridge, thereby reducing the precision of subsequent anomaly detection.

Therefore, it is desirable to provide a method and a system for monitoring and early warning of a safety status of a bridge to address the above issues.

### SUMMARY

In light of the above issues, the present disclosure provides a method and a system for monitoring and early warning of a safety status of a bridge, which can accurately obtain an overall predicted status of a target bridge, thereby generating reliable early warning information to ensure bridge safety.

To achieve the above objective, one or more embodiments of the present disclosure provide a method for monitoring and early warning of a safety status of a bridge. The method comprises: performing three-dimensional (3D) scanning on a bridge to be monitored, and constructing a 3D model corresponding to the bridge to be monitored based on a 3D scanning result; determining, based on the 3D model, whether the bridge to be monitored is a new bridge or an old bridge; in response to determining that the bridge to be monitored is the new bridge, collecting first monitoring data of the bridge to be monitored in real time, determining a first monitoring data threshold set by analyzing the 3D model, performing a first comparison between the first monitoring data and the first monitoring data threshold set to obtain a first comparison result corresponding to the first comparison, and displaying the first comparison result in real time; and in response to determining that the bridge to be monitored is the old bridge, collecting second monitoring data of the bridge to be monitored in real time, determining a second monitoring data threshold set by analyzing the 3D model, performing a second comparison between the second monitoring data and the second threshold to obtain a second comparison result corresponding to the second comparison, and displaying the second comparison result in real time.

In some embodiments, the method further comprises: remotely notifying personnel for processing based on the first comparison result or the second comparison result.

In some embodiments, the determining a first monitoring data threshold set includes: performing a simulation on the 3D model of the bridge to be monitored to determine a first simulation model corresponding to the bridge to be monitored; presetting a plurality of first simulation test conditions and performing a first simulation test on the first simulation model under each of the first simulation test conditions; and determining the first monitoring data threshold set based on a test result of the first simulation test, wherein the first monitoring data threshold set includes a first vertical load threshold, a first angular variation threshold, a first displacement variation threshold, a second vertical load threshold, a second angular variation threshold, and a second displacement variation threshold.

In some embodiments, the determining a second monitoring data threshold set includes: performing a simulation on the 3D model of the bridge to be monitored to determine a second simulation model corresponding to the bridge to be monitored; presetting a plurality of second simulation test conditions and performing a second simulation test on the second simulation model under each of the second simulation test conditions; determining the second monitoring data threshold set based on a test result of the second simulation test, wherein the second monitoring data threshold set includes a third angular variation threshold, a third displacement variation threshold, a fourth angular variation threshold, and a fourth displacement variation threshold.

In some embodiments, the first monitoring data includes a vertical load, an angular variation, and a displacement variation, and the obtaining a first comparison result corresponding to the first comparison includes: in response to the vertical load, the angular variation, and the displacement variation in the first monitoring data being less than the first vertical load threshold, the first angular variation threshold, and the first displacement variation threshold in the first monitoring data threshold set, respectively, performing normal monitoring; in response to any one or more of the vertical load, the angular variation, and the displacement variation being greater than or equal to the second vertical load threshold, second angular variation threshold, and second displacement variation threshold in the first monitoring data threshold set, respectively, stopping traffic on the bridge to be monitored and notifying personnel via a wireless communication device; and in response to any one or more of the vertical load, the angular variation, and the displacement variation being within corresponding threshold ranges in the first monitoring data threshold set, applying the vertical load, the angular variation, and the displacement variation in the first monitoring data as simulation variations to the first simulation model to obtain a first simulation result, and determining whether an abnormality exists based on the first simulation result, wherein if the abnormality exists, notifying the personnel via the wireless communication device, and if no abnormality exists, continuing the normal monitoring.

In some embodiments, the second monitoring data includes an angular variation and a displacement variation, and the obtaining a second comparison result corresponding to the second comparison includes: in response to the angular variation and the displacement variation in the second monitoring data being less than the third angular variation threshold and the third displacement variation threshold in the second monitoring data threshold set, respectively, performing normal data monitoring; in response to any one or more of the angular variation and the displacement variation being greater than or equal to the fourth angular variation threshold and the fourth displacement variation threshold in the second monitoring data threshold set, respectively, stopping traffic on the bridge to be monitored and notifying personnel via a wireless communication device; in response to any one or more of the angular variation and the displacement variation being within corresponding threshold ranges in the second monitoring data threshold set, applying the angular variation and the displacement variation as simulation inputs to the second simulation model to obtain a second simulation result, and determining whether an abnormality exists based on the second simulation result, wherein if the abnormality exists, notifying the personnel via the wireless communication device, and if no abnormality exists, continuing the normal monitoring.

In some embodiments, the determining, based on the 3D model, whether the bridge to be monitored is a new bridge or an old bridge includes: constructing an identification model, inputting the 3D scanning result into the identification model for processing, and determining whether the bridge to be monitored is the new bridge or the old bridge based on a processing result of the identification model.

One or more embodiments of the present disclosure further provide a system for monitoring and early warning of a safety status of a bridge. The system comprises an acquisition module, a determination module, a first warning module, and a second warning module. The acquisition module is configured to perform three-dimensional (3D) scanning on a bridge to be monitored, and construct a 3D model corresponding to the bridge to be monitored based on a 3D scanning result. The determination module is configured to determine, based on the 3D model, whether the bridge to be monitored is a new bridge or an old bridge. The first warning module is configured to, in response to determining that the bridge to be monitored is the new bridge, collect first monitoring data of the bridge to be monitored in real time, determine a first monitoring data threshold set by analyzing the 3D model, perform a first comparison between the first monitoring data and the first monitoring data threshold set to obtain a first comparison result corresponding to the first comparison, and display the first comparison result in real time. The second warning module is configured to, in response to determining that the bridge to be monitored is the old bridge, collect second monitoring data of the bridge to be monitored in real time, determine a second monitoring data threshold set by analyzing the 3D model, perform a second comparison between the second monitoring data and the second threshold to obtain a second comparison result corresponding to the second comparison, and display the second comparison result in real time.

Through the aforementioned technical solution, compared to existing technologies, one or more embodiments of the present disclosure provide a method and a system for monitoring and early warning of a safety status of a bridge. By determining whether a bridge to be monitored is a new bridge or an old bridge based on recognition results of a 3D model of the bridge to be monitored, corresponding simulation tests are conducted according to different judgment outcomes to determine monitoring data and corresponding actual monitoring threshold range for the bridge to be monitored. By comparing the monitored data of the bridge to be monitored with monitoring thresholds, the safety status of the bridge to be monitored can be more accurately assessed, thereby generating reliable early warning information to ensure bridge safety.

### BRIEF DESCRIPTION OF THE DRAWINGS

To more clearly illustrate the embodiments of the present disclosure or the technical solutions in the existing technologies, the following briefly introduces the accompanying drawings required for describing the embodiments of the present disclosure. Obviously, the drawings in the following description are merely illustrative of the embodiments of the present disclosure. For those skilled in the art, other drawings may be derived from the provided illustrations without creative effort.

FIG. 1 is a flowchart of an exemplary process of a method for monitoring and early warning of a safety status of a bridge according to some embodiments of the present disclosure.

FIG. 2 is a structural block diagram of a system for monitoring and early warning of a safety status of a bridge according to some embodiments of the present disclosure.

### DETAILED DESCRIPTION

In order to provide a clearer understanding of the technical solutions of the embodiments described in the present disclosure, a brief introduction to the drawings required in the description of the embodiments is given below. It is evident that the drawings described below are merely some examples or embodiments of the present disclosure, and for those skilled in the art, the present disclosure may be applied to other similar situations without exercising creative labor. Unless otherwise indicated or stated in the context, the same reference numerals in the drawings represent the same structures or operations.

It should be understood that the terms “system,” “device,” “unit,” and/or “module” used herein are ways for distinguishing different levels of components, elements, parts, or assemblies. However, if other terms can achieve the same purpose, they may be used as alternatives.

As indicated in the present disclosure and in the claims, the singular forms “a,” “an,” and “the” may be intended to include the plural forms as well, unless the context clearly indicates otherwise. The term “and/or” as used in the claims and the specification includes any and all combinations of one or more of the associated listed items. In general, the terms “comprise,” “comprises,” and/or “comprising,” “include,” “includes,” and/or “including,” when used in this disclosure, specify the presence of stated features, integers, steps, operations, elements, and/or components, but do not preclude the presence or addition of one or more other features, integers, steps, operations, elements, components, and/or groups thereof.

Flowcharts are used in the present disclosure to illustrate the operations performed by the system according to the embodiments described herein. It should be understood that the operations may not necessarily be performed in the exact sequence depicted. Instead, the operations may be performed in reverse order or concurrently. Additionally, other operations may be added to these processes, or one or more operations may be removed.

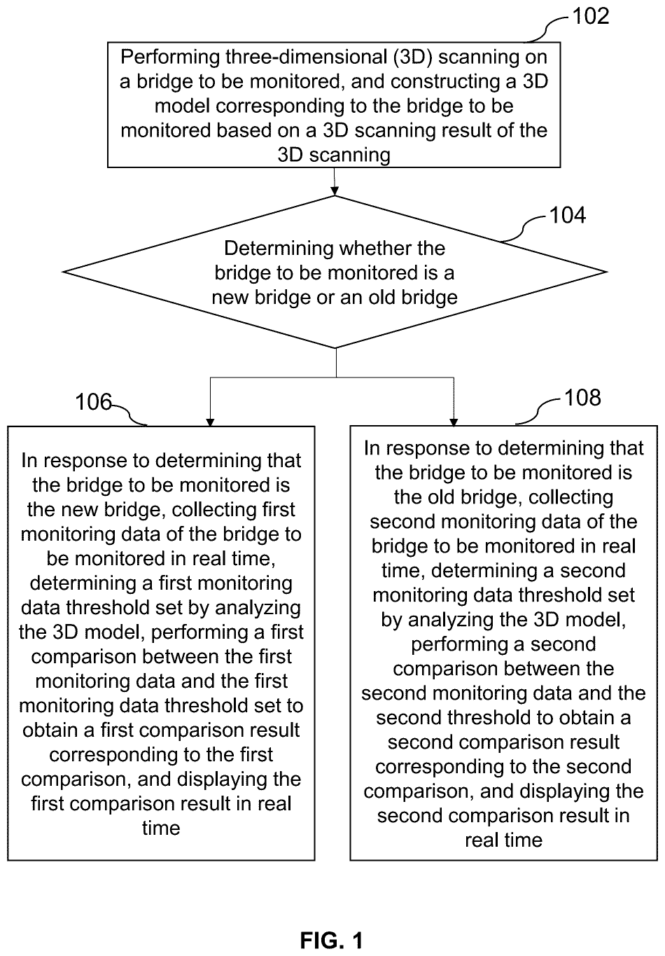

FIG. 1 is a flowchart of an exemplary process of a method for monitoring and early warning of a safety status of a bridge according to some embodiments of the present disclosure. In some embodiments, the method illustrated in FIG. 1 may be executed by a processing device (e.g., a computer, etc.) with computing capabilities and includes the following operations.

Operation 102, performing three-dimensional (3D) scanning on a bridge to be monitored, and constructing a 3D model corresponding to the bridge to be monitored based on a 3D scanning result of the 3D scanning.

The bridge to be monitored refers to a bridge that is pending or currently undergoing safety condition monitoring. Types of the bridge to be monitored may include a beam bridge, an arch bridge, a suspension bridge, etc.

3D scanning is a non-contact data acquisition technology that captures 3D coordinate points (i.e., point cloud data) of a surface of an object (e.g., the bridge to be monitored) using a measurement device to generate geometric and texture information of the bridge to be monitored. The 3D scanning may be implemented via a laser, a radar, an optical scanning system, or the like. In some embodiments, laser scanning may be used for the 3D scanning.

The 3D scanning result refers to a collection of raw data collected during the scanning process, containing a spatial position and attribute information of the surface of the bridge. The 3D scanning result may be stored in a point cloud format or a mesh format.

The 3D model refers to a digital model constructed based on the 3D scanning result. The 3D model reflects a geometric shape and a structural feature of the bridge and may be used for visualization, simulation, and analysis. The construction of the 3D model may include point cloud post-processing (e.g., registration and denoising) and generating a mesh model using a modeling software.

In some embodiments, the processing device may first deploy a 3D scanning device to collect data and then use a modeling tool to generate the 3D model. The executing entity may be an on-site engineer or an automated system, and the modeling tool may include a scanner and a computer software.

Operation 104, determining, based on the 3D model, whether the bridge to be monitored is a new bridge or an old bridge.

The new bridge refers to a bridge with a short construction time and no significant signs of aging or damage, and the structural feature thereof complies with current design standards.

The old bridge refers to a bridge that has been in service for a long time and may exhibit signs of degradation (e.g., corrosion, cracks, or the like).

In some embodiments, the processing device may use a computer vision algorithm or an expert software to analyze a structural attribute (e.g., surface texture, material properties, and geometric deformation) of the 3D model to determine whether the bridge to be monitored is the new bridge or the old bridge.

Operation 106, in response to determining that the bridge to be monitored is the new bridge, collecting first monitoring data of the bridge to be monitored in real time, determining a first monitoring data threshold set by analyzing the 3D model, performing a first comparison between the first monitoring data and the first monitoring data threshold set to obtain a first comparison result corresponding to the first comparison, and displaying the first comparison result in real time.

The first monitoring data refers to a set of sensor data collected in real time from the new bridge, used to monitor a structural health parameter (e.g., a displacement, a vibration, etc.) of the new bridge. In some embodiments, a sensor (e.g., a displacement meter, an accelerometer, etc.) may be installed on the bridge to be monitored to collect the first monitoring data.

The first monitoring data threshold set refers to a group of early warning thresholds determined based on the analysis of the 3D model of the new bridge, representing an upper limit and a lower limit of a safe parameter range, which may include a plurality of parameters. In some embodiments, the processing device may perform a simulation analysis on the 3D model of the new bridge and determine the first monitoring data threshold set based on the simulation result.

The first comparison refers to an operation that compares the first monitoring data with the first monitoring data threshold set to determine whether data values exceed corresponding thresholds.

The first comparison result refers to an output of the first comparison, indicating the safety status (e.g., normal, warning, etc.). The first comparison result may take the form of a Boolean value or a numerical difference. For example, 1 may indicate normal, 2 may indicate partial threshold exceedance, and 3 may indicate an early warning.

In some embodiments, the processing device may compare real-time collected values of the first monitoring data with an upper limit and a lower limit of the first monitoring data threshold set to determine whether the values exceed the limits, thereby obtaining the first comparison result.

In some embodiments, the first comparison result may be displayed in real time through a data visualization interface (e.g., a web-based dashboard), showing status text or charts. For example, the first comparison result (e.g., a displacement over the limit) may be displayed on an LED screen in a monitoring center with red color coding to indicate an alarm.

In some embodiments, the processing device may display the first comparison result in an interactive manner. For example, the processing device may overlay or superimpose the first comparison result on the 3D model using color coding. A user may click on, zoom in, or zoom out of different parts of the 3D model to view detailed information. Abnormal regions in the 3D model indicating structural regions where the first monitoring data exceeds threshold values may be identified, helping the user take targeted countermeasures to prevent or mitigate risk events.

Operation 108, in response to determining that the bridge to be monitored is the old bridge, collecting second monitoring data of the bridge to be monitored in real time, determining a second monitoring data threshold set by analyzing the 3D model, performing a second comparison between the second monitoring data and the second threshold to obtain a second comparison result corresponding to the second comparison, and displaying the second comparison result in real time.

The second monitoring data refers to a set of sensor data collected in real time from the old bridge, which is used to monitor the structural health parameter (e.g., a displacement, a vibration, etc.) of the old bridge.

The second monitoring data threshold set refers to a group of early warning thresholds determined based on the analysis of the 3D model of the old bridge.

The second comparison refers to an operation of comparing the second monitoring data with the second monitoring data threshold set to determine whether data values exceed corresponding thresholds.

The second comparison result refers to an output of the second comparison and indicates the safety status (e.g., normal, warning, etc.). The second comparison result may take the form of a Boolean value or a numerical difference. For example, 1 may indicate normal, 2 may indicate partial threshold exceedance, and 3 may indicate an early warning.

In some embodiments, the processing device may compare real-time collected values of the second monitoring data with an upper limit and a lower limit of the second monitoring data threshold set to determine whether data values exceed the limits, thereby obtaining the second comparison result.

In some embodiments, the real-time display manner for the second comparison result may be similar to the real-time display manner for the first comparison result.

In some embodiments, the processing device may display the second comparison result in an interactive manner. For example, the processing device may overlay or superimpose the first comparison result on the 3D model using color coding. The user may click on, zoom in, or zoom out of different parts of the 3D model to view detailed information. Abnormal regions in the 3D model indicating structural regions where the first monitoring data exceeds threshold values may be identified, helping the user take targeted countermeasures to prevent or mitigate risk events.

More descriptions regarding operation 108 may be found in the relevant description of operation 106, with the primary difference being whether the bridge to be monitored is the new bridge or the old bridge. The execution manners for operations 106 and 108 are similar.

In some embodiments, the processing device may remotely notify personnel for processing based on the first comparison result or the second comparison result. For example, the personnel may be notified remotely via a short message service (SMS), an email, or a phone call. The personnel may include operation and maintenance staff, regulatory staff, or the like, responsible for the bridge to be monitored.

In some embodiments, determining the first monitoring data threshold set may include the following operations.

If the bridge to be monitored is the new bridge, the first monitoring data is collected in real time. The first monitoring data includes a vertical load, an angular variation, and a displacement variation.

The vertical load refers to a load acting in a vertical direction on the bridge, reflecting forces induced by vehicle traffic, a self-weight of the bridge, or the like.

The angular variation refers to a change in angle at a part (e.g., a bearing) of the bridge, indicating a degree of torsional deformation of the structure of the bridge.

The displacement variation refers to a linear positional offset at a critical point (e.g., a mid-span position) of the bridge, indicating a flexural deformation.

A simulation is performed on the 3D model of the bridge to be monitored to determine a first simulation model corresponding to the bridge to be monitored.

The simulation refers to using a computer-based technique to mimic a physical process (e.g., a mechanical response) and predict a behavior of the bridge under a load. The first simulation model refers to a digital model converted from the 3D model of the new bridge, configured to enable the computation of physical responses by incorporating a material property, a boundary condition, etc. In some embodiments, the processing device may input the 3D model of the bridge to be monitored into a simulation software (e.g., ABAQUS), define parameters such as the material property, the boundary condition, a load type, etc., and obtain the first simulation model through analysis performed by the simulation software.

A plurality of first simulation test conditions may be preset, and a first simulation test on the first simulation model may be performed under each of the first simulation test conditions. Based on a test result of the first simulation test, the first monitoring data threshold set is determined.

The first monitoring data threshold set includes a first vertical load threshold, a first angular variation threshold, a first displacement variation threshold, a second vertical load threshold, a second angular variation threshold, and a second displacement variation threshold. The first simulation test condition refers to a predefined test condition used to simulate the new bridge. The threshold refers to a critical criterion value, and when data exceeds the threshold, an alarm or a corresponding predefined condition may be triggered.

In some embodiments, the first simulation test conditions may include a plurality of vertical load test parameters, a plurality of angular variation test parameters, and a plurality of displacement variation test parameters. Additionally, the first simulation test conditions may include a combined test condition of the vertical load test parameters and the angular variation test parameters, a combined test condition of the vertical load test parameters and the displacement variation test parameters, a combined test condition of the angular variation test parameters and the displacement variation test parameters, and a combined test condition of the vertical load test parameters, the angular variation test parameters, and the displacement variation test parameters.

During simulation testing, each of the parameter types (e.g., the vertical load test parameters, the angular variation test parameters, and the displacement variation test parameters) is tested individually using the corresponding test parameters to determine an independent threshold range (e.g., an upper limit and a lower limit) corresponding to each of the parameter types, thus obtaining a set of threshold ranges. Then, another set of independent threshold ranges (e.g., upper limits and lower limits) is determined using the combined test conditions. Finally, the two sets of independent threshold ranges are weighted and fused to obtain the first vertical load threshold, the first angular variation threshold, the first displacement variation threshold, the second vertical load threshold, the second angular variation threshold, and the second displacement variation threshold. The combined test condition refers to a simulation test condition involving two or more types of parameters used in combination.

In some embodiments of the present disclosure, by comprehensively considering the actual structure of the bridge to be monitored and different simulation test conditions, corresponding practical threshold ranges can be determined, thereby improving the accuracy of anomaly detection for the bridge.

In some embodiments, determining the second monitoring data threshold set may include the following operations:

In response to determining that the bridge to be monitored is the old bridge, second monitoring data of the bridge to be monitored may be collected in real time. The second monitoring data includes an angular variation and a displacement variation. The angular variation refers to a change in angle at a part (e.g., a support base, a joint, etc.) of the bridge, reflecting the degree of torsional deformation of the structure of the bridge. The displacement variation refers to the linear positional offset at key points of the bridge (e.g., mid-span), reflecting structural deflection or settlement.

A simulation is performed on the 3D model of the bridge to be monitored to determine a second simulation model corresponding to the bridge to be monitored. The second simulation model refers to a digital model capable of computing physical responses, which is converted from the 3D model of the existing bridge. The simulation analysis manner may be the same as the simulation analysis manner used for obtaining the first simulation model and will not be repeated here.

A plurality of second simulation test conditions are preset, and a second simulation test may be performed on the second simulation model under each of the second simulation test conditions. Based on a test result of the second simulation test, the second monitoring data threshold set is determined. The second monitoring data threshold set includes a third angular variation threshold, a third displacement variation threshold, a fourth angular variation threshold, and a fourth displacement variation threshold. A second simulation test condition refers to a preset test condition for performing simulation tests on the old bridge.

In some embodiments, the second simulation test conditions may include a plurality of angular variation test parameters and a plurality of displacement variation test parameters. In addition, the second simulation test conditions may also include a combined test condition comprising the angular variation test parameters and the displacement variation test parameters.

During simulation testing, each of the parameter types (e.g., the angular variation test parameters and the displacement variation test parameters) is tested individually using the corresponding test parameters to determine an independent threshold range (e.g., an upper limit and a lower limit) corresponding to each of the parameter types, thus obtaining a set of threshold ranges. Then, another set of independent threshold ranges (e.g., upper limits and lower limits) is determined using the combined test condition. Finally, the two sets of independent threshold ranges are weighted and fused to obtain the third angular variation threshold, the third displacement variation threshold, the fourth angular variation threshold, and the fourth displacement variation threshold. By comprehensively considering the actual structure of the bridge to be monitored and different simulation test conditions, corresponding practical threshold ranges can be determined, thereby improving the accuracy of anomaly detection for the bridge.

In some embodiments, obtaining the first comparison result corresponding to the first comparison may include the following operations.

In response to the vertical load, the angular variation, and the displacement variation in the first monitoring data being less than the first vertical load threshold, the first angular variation threshold, and the first displacement variation threshold in the first monitoring data threshold set, respectively, normal monitoring may be performed. That is to say, in subsequent time periods, the bridge to be monitored continues to be monitored using a normal monitoring technique (e.g., the method for monitoring and early warning of a safety status of a bridge provided in one or more the embodiments of the present disclosure), and relevant data is collected.

In response to any one or more of the vertical load, the angular variation, and the displacement variation being greater than or equal to the second vertical load threshold, second angular variation threshold, and second displacement variation threshold in the first monitoring data threshold set, respectively, traffic is stopped on the bridge to be monitored and the personnel may be notified via a wireless communication device.

In response to any one or more of the vertical load, the angular variation, and the displacement variation being within corresponding threshold ranges in the first monitoring data threshold set (i.e., the vertical load is between the first vertical load threshold and the second vertical load threshold, the angular variation is between the first angular variation threshold and the second angular variation threshold, and the displacement variation is between the first displacement variation threshold and the second displacement variation threshold), the vertical load, the angular variation, and the displacement variation may be applied as simulation variations to the first simulation model to obtain the first simulation result, and whether an abnormal condition exists may be determined based on the second simulation result. If the abnormality exists, the personnel may be notified via the wireless communication device, and if no abnormality exists, the normal monitoring may be continued.

For example, the processing device may apply the simulation variations as data load to the first simulation model in the simulation software, determine a key indicator (e.g., a maximum stress), and compare the key indicator with a material strength. If the first simulation result exceeds a safety standard (e.g., the stress exceeds a yield strength), it is determined that the abnormal exists; otherwise, it is determined that no abnormality exists.

In some embodiments, obtaining the second comparison result corresponding to the second comparison may include the following operations.

In response to the angular variation and the displacement variation in the second monitoring data being less than the third angular variation threshold and the third displacement variation threshold in the second monitoring data threshold set, respectively, the normal data monitoring may be performed.

In response to any one or more of the angular variation and the displacement variation being greater than or equal to the fourth angular variation threshold and the fourth displacement variation threshold in the second monitoring data threshold set, respectively, traffic on the bridge to be monitored is stopped, and the personnel may be notified via the wireless communication device.

In response to any one or more of the angular variation and the displacement variation being within corresponding threshold ranges in the second monitoring data threshold set (i.e., the angular variation is between the third angular variation threshold and the fourth angular variation threshold, and the displacement variation is between the third displacement variation threshold and the fourth displacement variation threshold), the angular variation and displacement variation are applied as simulation variations to the second simulation model to obtain a second simulation result. Based on the second simulation result, whether an abnormal condition exists is determined. If the abnormality exists, the personnel may be notified via the wireless communication device; if no abnormality exists, the normal monitoring is continued.

For example, the processing device may apply the simulation variations as boundary conditions (e.g., the angular variation as a rotational constraint, and the displacement variation as a prescribed displacement load) to the second simulation model in the simulation software, and determine a key indicator (e.g., a crack propagation rate), which is then compared with a threshold value of the key indicator. If the second simulation result exceeds a safety standard (e.g., the crack propagation rate exceeds a crack propagation rate threshold), it is determined that an abnormal condition exists; otherwise, it is determined that no abnormality exists.

In some embodiments, determining whether the bridge to be monitored is the new bridge or the old bridge based on the 3D model may include: constructing an identification model, inputting the 3D model or the 3D scanning result into the identification model for processing, and determining whether the bridge to be monitored is the new bridge or the old bridge based on a processing result of the identification model.

In some embodiments, the identification model may be a convolutional neural network (CNN), which determines whether the bridge to be monitored is the new bridge or the old bridge by analyzing input data to identify the structural feature and a usage condition of the bridge. The identification model may be obtained by training the convolutional neural network with training data. For example, historical 3D models or 3D scanning results of bridges may be used as training samples, and manually labeled as the new bridge or the old bridge. A loss function is constructed based on outputs of the CNN and corresponding labels, and parameters of the CNN are adjusted to minimize the value of the loss function, thereby reducing a discrepancy between the outputs of the CNN and the labels. When a preset condition is met, the training is completed and a trained CNN (i.e., the identification model) is obtained. The preset condition may include a count of training iterations reaching a predefined value (e.g., 10,000 iterations), convergence of the loss function, or the like.

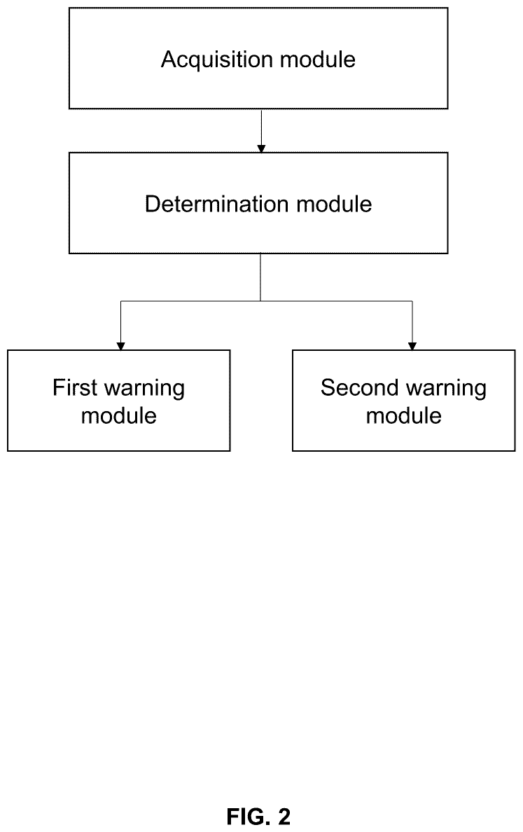

Referring to FIG. 2, one or more embodiments of the present disclosure further provide a system for monitoring and early warning of a safety status of a bridge. The system comprises an acquisition module, a determination module, a first warning module, and a second warning module.

The acquisition module is configured to perform three-dimensional (3D) scanning on a bridge to be monitored, and constructing a 3D model corresponding to the bridge to be monitored based on a 3D scanning result.

The determination module is configured to determine, based on the 3D model, whether the bridge to be monitored is a new bridge or an old bridge.

The first warning module is configured to, in response to determining that the bridge to be monitored is the new bridge, collect first monitoring data of the bridge to be monitored in real time, determine a first monitoring data threshold set by analyzing the 3D model, perform a first comparison between the first monitoring data and the first monitoring data threshold set to obtain a first comparison result corresponding to the first comparison, and display the first comparison result in real time.

The second warning module is configured to, in response to determining that the bridge to be monitored is the old bridge, collect second monitoring data of the bridge to be monitored in real time, determine a second monitoring data threshold set by analyzing the 3D model, perform a second comparison between the second monitoring data and the second threshold to obtain a second comparison result corresponding to the second comparison, and display the second comparison result in real time.

The embodiments in the present disclosure are described in a progressive manner, with each embodiment emphasizing the differences from other embodiments. For parts that are the same or similar among the various embodiments, reference may be made to one another. As for the disclosed devices in the embodiments, since they correspond to the method disclosed in the embodiments, their descriptions are relatively brief, and the relevant details may be referred to in the method section.

Having thus described the basic concepts, it may be rather apparent to those skilled in the art after reading this detailed disclosure that the foregoing detailed disclosure is intended to be presented by way of example only and is not limiting. Various alterations, improvements, and modifications may occur and are intended to those skilled in the art, though not expressly stated herein. These alterations, improvements, and modifications are intended to be suggested by this disclosure and are within the spirit and scope of the exemplary embodiments of this disclosure.

Moreover, certain terminology has been used to describe embodiments of the present disclosure. For example, the terms “one embodiment,” “an embodiment,” and/or “some embodiments” mean that a particular feature, structure, or characteristic described in connection with the embodiment is included in at least one embodiment of the present disclosure. Therefore, it is emphasized and should be appreciated that two or more references to “an embodiment” or “one embodiment” or “an alternative embodiment” in various portions of the present disclosure are not necessarily all referring to the same embodiment. Furthermore, the particular features, structures, or characteristics may be combined as suitable in one or more embodiments of the present disclosure.

Furthermore, the recited order of processing elements or sequences, or the use of numbers, letters, or other designations, therefore, is not intended to limit the claimed processes and methods to any order except as may be specified in the claims. Although the above disclosure discusses through various examples what is currently considered to be a variety of useful embodiments of the disclosure, it is to be understood that such detail is solely for that purpose and that the appended claims are not limited to the disclosed embodiments, but, on the contrary, are intended to cover modifications and equivalent arrangements that are within the spirit and scope of the disclosed embodiments. For example, although the implementation of various components described above may be embodied in a hardware device, it may also be implemented as a software-only solution, e.g., an installation on an existing server or mobile device.

Similarly, it should be appreciated that in the foregoing description of embodiments of the present disclosure, various features are sometimes grouped together in a single embodiment, figure, or description thereof to streamline the disclosure aiding in the understanding of any one or more of the various inventive embodiments. This method of disclosure, however, is not to be interpreted as reflecting an intention that the claimed object matter requires more features than are expressly recited in each claim. Rather, inventive embodiments lie in less than all features of a single foregoing disclosed embodiment.

In some embodiments, the numbers expressing quantities, properties, and so forth, used to describe and claim certain embodiments of the application are to be understood as being modified in some instances by the term “about,” “approximate,” or “substantially.” For example, “about,” “approximate” or “substantially” may indicate ±20% variation of the value it describes, unless otherwise stated. Accordingly, in some embodiments, the numerical parameters set forth in the written description and attached claims are approximations that may vary depending upon the desired properties sought to be obtained by a particular embodiment. In some embodiments, the numerical parameters should be construed in light of the count of reported significant digits and by applying ordinary rounding techniques. Notwithstanding that the numerical ranges and parameters setting forth the broad scope of some embodiments of the application are approximations, the numerical values set forth in the specific examples are reported as precisely as practicable.

Each of the patents, patent applications, publications of patent applications, and other material, such as articles, books, specifications, publications, documents, things, and/or the like, referenced herein is hereby incorporated herein by this reference in its entirety for all purposes, excepting any prosecution file history associated with same, any of same that is inconsistent with or in conflict with the present document, or any of same that may have a limiting affect as to the broadest scope of the claims now or later associated with the present document. By way of example, should there be any inconsistency or conflict between the description, definition, and/or the use of a term associated with any of the incorporated material and that associated with the present document, the description, definition, and/or the use of the term in the present document shall prevail.

In closing, it is to be understood that the embodiments of the application disclosed herein are illustrative of the principles of the embodiments of the application. Other modifications that may be employed may be within the scope of the application. Thus, by way of example, but not of limitation, alternative configurations of the embodiments of the application may be utilized in accordance with the teachings herein. Accordingly, embodiments of the present application are not limited to that precisely as shown and described.

What is claimed is:

1. A method for monitoring and early warning of a safety status of a bridge, comprising:
performing three-dimensional (3D) scanning on a bridge to be monitored, and constructing a 3D model based on a 3D scanning result of the 3D scanning;
determining, based on the 3D model, whether the bridge to be monitored is a new bridge or an old bridge;
in response to determining that the bridge to be monitored is the new bridge,
collecting first monitoring data of the bridge to be monitored in real time,
determining a first monitoring data threshold set by analyzing the 3D model,
performing a comparison between the first monitoring data and the first monitoring data threshold set to obtain a first comparison result corresponding to the comparison, and displaying the first comparison result in real time; and
in response to determining that the bridge to be monitored is the old bridge,
collecting second monitoring data of the bridge to be monitored in real time,
determining a second monitoring data threshold set by analyzing the 3D model,
performing a comparison between the second monitoring data and the second threshold to obtain a second comparison result corresponding to the comparison, and displaying the second comparison result in real time.

2. The method of claim 1, further comprising:
remotely notifying personnel for processing based on the first comparison result or the second comparison result.

3. The method of claim 1, wherein the determining a first monitoring data threshold set includes:
in response to determining that the bridge to be monitored is the new bridge, collecting first monitoring data of the bridge to be monitored in real time, wherein the first monitoring data includes a vertical load, an angular variation, and a displacement variation;
performing a simulation on the 3D model of the bridge to be monitored to determine a corresponding simulation model;
presetting a plurality of first simulation test conditions and performing a simulation test on the simulation model under each of the first simulation test conditions; and
determining the first monitoring data threshold set based on a test result of the simulation test, wherein the first monitoring data threshold set includes a first vertical load threshold, a first angular variation threshold, a first displacement variation threshold, a second vertical load threshold, a second angular variation threshold, and a second displacement variation threshold.

4. The method of claim 1, wherein the determining a second monitoring data threshold set includes:
in response to determining that the bridge to be monitored is the old bridge, collecting second monitoring data of the bridge to be monitored in real time, wherein the second monitoring data includes an angular variation and a displacement variation;
performing a simulation on the 3D model of the bridge to be monitored to determine a corresponding simulation model;
presetting a plurality of second simulation test conditions and performing a simulation test on the simulation model under each of the second simulation test conditions;
determining the second monitoring data threshold set based on a test result of the simulation test, wherein the second monitoring data threshold set includes a third angular variation threshold, a third displacement variation threshold, a fourth angular variation threshold, and a fourth displacement variation threshold.

5. The method of claim 3, wherein the first comparison result is obtained through a process including:
in response to the vertical load, the angular variation, and the displacement variation in the first monitoring data being less than the first vertical load threshold, the first angular variation threshold, and the first displacement variation threshold, respectively, performing normal monitoring;
in response to any one or more of the vertical load, the angular variation, and the displacement variation being greater than or equal to the second vertical load threshold, second angular variation threshold, and second displacement variation threshold, respectively, stopping traffic on the bridge to be monitored and notifying personnel via a wireless communication device; and
in response to any one or more of the vertical load, the angular variation, and the displacement variation being within corresponding threshold ranges, applying the vertical load, the angular variation, and the displacement variation in the first monitoring data as simulation variations to the simulation model to obtain a corresponding simulation result, and determining whether an abnormality exists based on the corresponding simulation result, wherein if the abnormality exists, notifying the personnel via the wireless communication device, and if no abnormality exists, continuing the normal monitoring.

6. The method of claim 4, wherein the second comparison result is obtained through a process including:
in response to the angular variation and the displacement variation being less than the third angular variation threshold and the third displacement variation threshold, respectively, performing normal data monitoring;
in response to any one or more of the angular variation and the displacement variation being greater than or equal to the fourth angular variation threshold and the fourth displacement variation threshold in the second monitoring data threshold set, respectively, stopping traffic on the bridge to be monitored and notifying personnel via a wireless communication device;
in response to any one or more of the angular variation and the displacement variation being within corresponding threshold ranges, applying the angular variation and the displacement variation as simulation inputs to the simulation model to obtain a corresponding simulation result, and determining whether an abnormality exists based on the corresponding simulation result, wherein if the abnormality exists, notifying the personnel via the wireless communication device, and if no abnormality exists, continuing the normal monitoring.

7. The method of claim 1, wherein the determining whether the bridge to be monitored is a new bridge or an old bridge includes:
constructing an identification model,
inputting the 3D scanning result into the identification model for processing, and
determining whether the bridge to be monitored is the new bridge or the old bridge based on a processing result.

8. A system for monitoring and early warning of a safety status of a bridge, comprising:
an acquisition module, configured to perform three-dimensional (3D) scanning on a bridge to be monitored, and construct a 3D model corresponding to the bridge to be monitored based on a 3D scanning result of the 3D scanning;
a determination module, configured to determine, based on the 3D model, whether the bridge to be monitored is a new bridge or an old bridge;
a first warning module, configured to, in response to determining that the bridge to be monitored is the new bridge,
collect first monitoring data of the bridge to be monitored in real time,
determine a first monitoring data threshold set by analyzing the 3D model,
perform a comparison between the first monitoring data and the first monitoring data threshold set to obtain a first comparison result corresponding to the comparison, and display the first comparison result in real time;
a second warning module, configured to, in response to determining that the bridge to be monitored is the old bridge,
collect second monitoring data of the bridge to be monitored in real time,
determine a second monitoring data threshold set by analyzing the 3D model,
perform a comparison between the second monitoring data and the second threshold to obtain a second comparison result corresponding to the comparison, and display the second comparison result in real time.
